(19) United States
(12) Patent Application Publication
(10) Pub. No.: US 2015/0253154 A1
(43) Pub. Date: Sep. 10, 2015

(54) ROTATIONAL SENSOR

(71) Applicant: Dynapar Corporation, Gurnee, IL (US)

(72) Inventors: Kenneth Lee Dickinson, Columbus, OH (US); James Arthur Fuhrman, Pleasant Prarie, WI (US); August Allen Chasey, Peachtree City, GA (US); Mark Edward Langille, Lindenhurst, IL (US); Dale Wayne Taylor, Lindenhurst, IL (US)

(73) Assignee: DYNAPAR CORPORATION, Gurnee, IL (US)

(21) Appl. No.: 14/601,415

(22) Filed: Jan. 21, 2015

Related U.S. Application Data
(60) Provisional application No. 61/948,076, filed on Mar. 5, 2014.

(51) Int. Cl. G01D 5/12; G01R 33/09; G01D 5/14; G01R 33/07

(52) U.S. Cl. CPC G01D 5/12; G01R 33/07; G01R 33/09; G01D 5/142

(57) ABSTRACT

In an embodiment of a rotational sensor, a multi-pole magnet assembly comprises multiple magnets configured to rotate about a rotational axis of the rotational sensor, where the multi-pole magnet assembly is in a first plane perpendicular to the rotational axis. The magnetic sensor is arranged in a second plane also perpendicular to the rotational axis and in proximity to the multi-pole magnet assembly. Each magnet of the multiple magnets has poles aligned parallel to the rotational axis and perpendicular to the first plane of the magnetic sensor. In another embodiment, the magnetic sensor is arranged at a first radius away from the rotational axis, whereas the multiple magnets of the magnet assembly are arranged at a second radius, not equal to the first radius, away from the rotational axis. In yet another embodiment, a rotational sensor comprises a housing and rotatable shaft upon which the magnet assembly is mounted.

### CROSS-REFERENCE TO RELATED APPLICATION

The instant application claims the benefit of Provisional U.S. patent application Ser. No. 61/948,076 entitled “Encoder Feedback Device” and filed Mar. 5, 2014, the teachings of which are incorporated herein by this reference.

### FIELD

The instant disclosure relates generally to sensors or feedback devices and, in particular, to a rotational sensor or feedback encoder.

### BACKGROUND

Rotation detection sensors or rotary encoders (collectively referred to herein as “rotational sensors”) are common sensor devices. Many rotational sensors use a combination of a ball bearing system and optical sensor elements to measure the rotation of a rotating member, e.g., an axle, shaft, wheel, etc. Consistent and reliable operation of these devices tends to be problematic in heavy duty applications (e.g., agricultural equipment frequently in the presence of contaminants such as dirt, grease, water, etc. or corrosive materials such as fertilizer and/or applied chemicals).

Unfortunately, environments having relatively high levels of contaminants and/or high levels of corrosive substances tend to significantly reduce the lifetime of rotational sensors. In such environments, typical sensing elements such as optical sensors or contact potentiometers can easily become contaminated or degraded and subsequently fail. To combat these effects, rotational sensors often incorporate designs using rather elaborate sealing systems or housings, often times leading to increased manufacturing costs, increased maintenance needs and/or lower resolution readings.

Thus, it would be advantageous to provide a rotational sensor capable of operation in environments having relatively high levels of contaminants and/or high levels of corrosive substances and that overcome the limitations of existing rotational sensor designs.

### SUMMARY

In order to overcome the limitations of prior art techniques, the instant disclosure describes various embodiments of a rotational sensor comprising a magnetic sensor and a magnet assembly. In one embodiment, a multi-pole magnet assembly comprises multiple magnets configured to rotate about a rotational axis of the rotational sensor, where the multi-pole magnet assembly is in a first plane perpendicular to the rotational axis. The magnetic sensor is arranged in a second plane also perpendicular to the rotational axis and in proximity to the multi-pole magnet assembly. In this embodiment, each magnet of the multiple magnets has poles aligned parallel to the rotational axis and perpendicular to the first plane of the magnetic sensor.

In another embodiment, the magnetic sensor is arranged at a first radius away from the rotational axis, whereas the multiple magnets of the magnet assembly are arranged at a second radius, not equal to the first radius, away from the rotational axis.

In yet another embodiment, a rotational sensor comprises a housing having a housing central bore centered on and extending along a longitudinal axis of the housing. A rotatable shaft is configured to be received in the housing central bore via a first open end of the housing and, in turn, comprises a shaft central bore (which may be a blind bore) configured to receive a rotating member. The rotatable shaft also comprises an end surface substantially perpendicular to the longitudinal axis. At least one magnet is supported by the end surface of the rotatable shaft and is thereby able to rotate about the longitudinal axis. The at least one magnet may be arranged in proximity to the longitudinal axis, in proximity to a circumferential edge of the rotatable shaft or at any radial distance (relative to the longitudinal axis) therebetween. Additionally, poles of each of the at least one magnet are aligned parallel to the longitudinal axis. In an embodiment, the at least one magnet comprises four magnets. A magnetic sensor is arranged in a plane parallel to the end surface of the rotatable shaft and in proximity to the at least one magnet. The magnetic sensor may be arranged on a circuit board and the housing may be configured with a second open end (opposite the first open end) to receive the circuit board. An encapsulant may be arranged in the second open end covering the circuit board. In an embodiment, both the housing and rotatable shaft are fabricated from a non-magnetic material, such as one or more synthetic polymer materials or non-magnetic metals. A sleeve bearing, which may also be fabricated from a synthetic polymer, may be arranged between the housing and the rotatable shaft.

### BRIEF DESCRIPTION OF THE DRAWINGS

The features described in this disclosure are set forth with particularity in the appended claims. These features will become apparent from consideration of the following detailed description, taken in conjunction with the accompanying drawings. One or more embodiments are now described, by way of example only, with reference to the accompanying drawings wherein like reference numerals represent like elements and in which:

FIG. 1 is an isometric view of a magnetic sensor and a magnet assembly in accordance with the instant disclosure;

FIG. 2 is a cross-sectional view of the magnetic sensor and multi-pole magnet assembly of FIG. 1 taken along section plane II-II;

FIG. 3 is a cross-sectional view of the magnetic sensor and multi-pole magnet assembly of FIG. 1 taken along section plane III-III;

FIGS. 4 and 5 are bottom and top isometric views, respectively, of an embodiment of a rotational sensor in accordance with the instant disclosure;

FIG. 6. is an exploded view of the rotational sensor of FIGS. 4 and 5; and

FIG. 7 is a partial cross-sectional elevation view of the rotational sensor of FIGS. 4-6.

### DETAILED DESCRIPTION OF THE PRESENT EMBODIMENTS

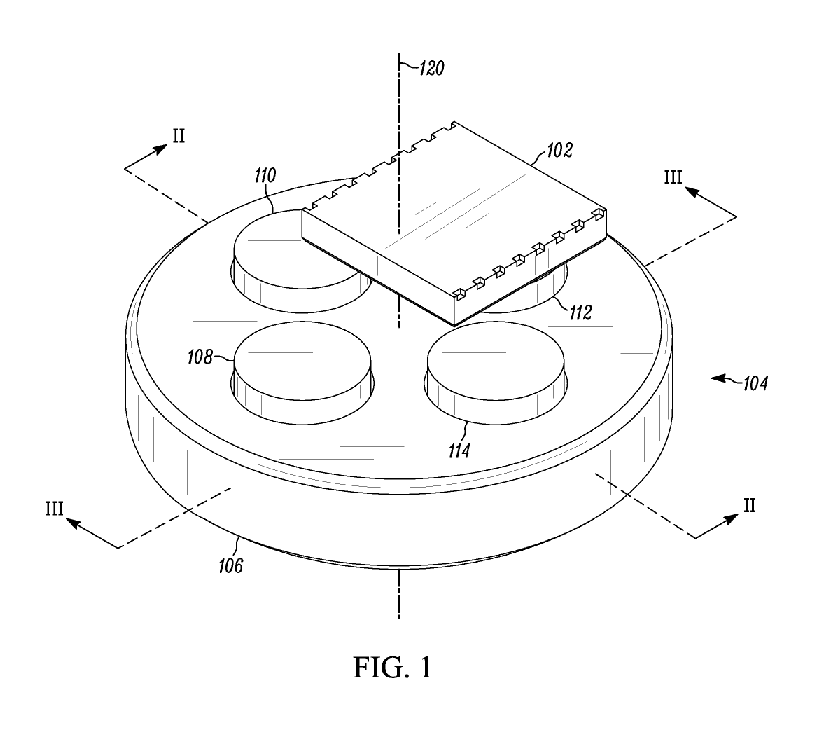

FIG. 1 illustrates a magnetic sensor 102 and a magnet assembly 104 in accordance with the instant disclosure. The magnetic sensor 102 may comprise any suitable device capable of detecting magnetic fields or changes in such magnetic fields. For example, in one embodiment, the magnetic sensor 102 may comprise a Hall Effect sensor such as an iC-MH sensor manufactured by iC-Haus GmbH. However, the instant disclosure is not limited by the particular type of magnetic sensor employed. As a further example, a magneto-resistive sensor may be equally employed for this purpose. In practice, the magnetic sensor 102 may be embodied as an integrated circuit arranged on a suitable circuit board (not shown), which circuit board may include any additional electric circuitry necessary to operate the magnetic sensor 102 and obtain useful data therefrom. Such implementations are well known in the art and are therefore not described in further detail here.

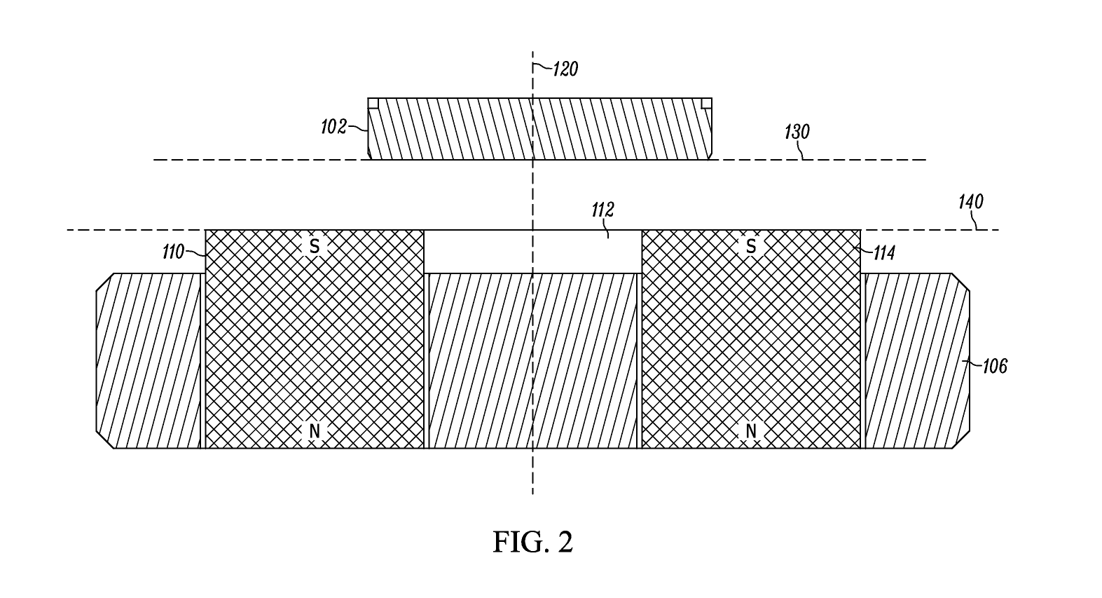

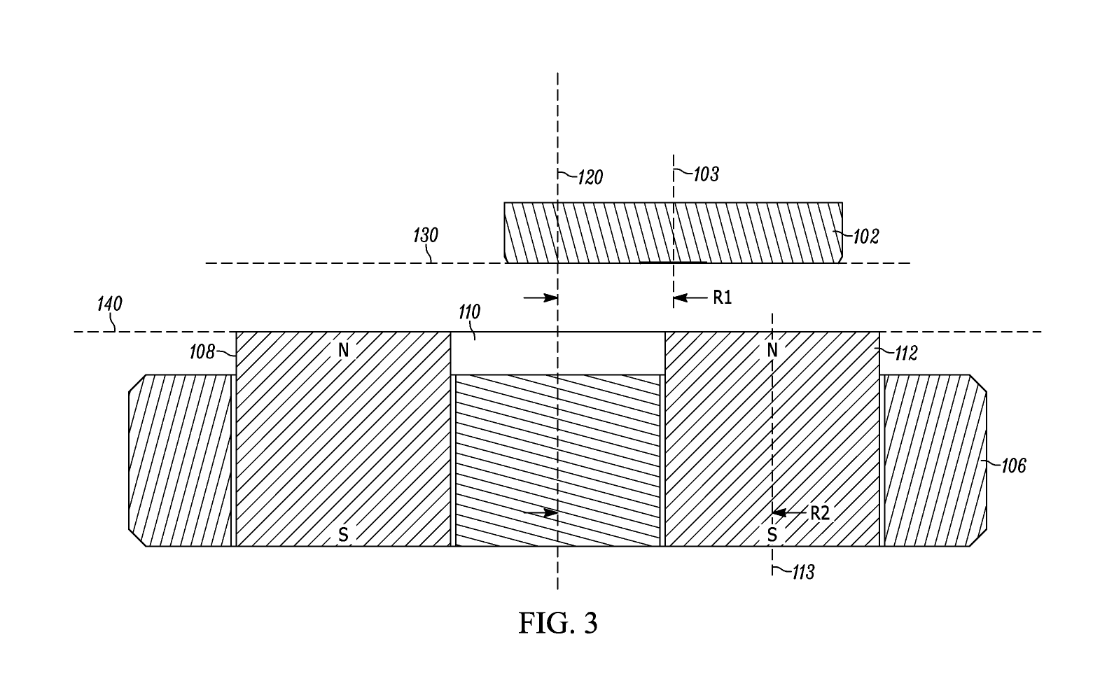

Generally, the magnet assembly 104 comprises at least one magnet, though, in the illustrated embodiment, the assembly 104 comprises four magnets 108, 110, 112, 114. The magnet assembly 104 in the illustrated embodiment comprises a body 106 configured to fixedly maintain at least one magnet therein. Although the body 106 illustrated in FIG. 1 has a generally circular shape, it is noted that this is not a requirement. In an embodiment, the body 106 is fabricated from 300 Series stainless steel, though any of a number of suitable non-magnetic materials, including synthetic polymers such as 30% glass-filled polybutylene terephthalate (PBT), may be used for this purpose. As shown in FIGS. 2 and 3, the body 106 may comprise openings configured to receive the magnets 108, 110, 112, 114, which openings are arranged in symmetrical relationships to each other relative to a rotational axis 120. However, it is noted that such symmetry is not a requirement and it may be desirable in some applications to arrange the magnets in according to non-symmetrical relationships. (It is noted that, as used herein, terms like “symmetrical,” “parallel,” “perpendicular,” “substantially,” and other words of degree or relationship are understood to describe conditions achievable within normal manufacturing tolerances.) In order to maintain the one or more magnets in their corresponding openings, a suitable adhesive may be employed or, alternatively, the openings and their corresponding magnets may be configured to ensure a force fit. In an embodiment, the openings (and, consequently, the magnets 108, 110, 112, 114) are equally spaced angularly from each other and radially from the rotational axis 120, i.e., they are spaced equidistant from each other along the circumference of a circle upon which they all reside. For example, in the illustrated embodiment, each of the magnets 108, 110, 112, 114 is separated by 90 degrees from its neighbors, and with central axes of each of the magnets positioned equidistant from the rotational axis 120.

A feature of the magnets 108, 110, 112, 114 is that each magnet is arranged such that its poles are aligned parallel to the rotational axis 120. This is illustrated in FIGS. 2 and 3 where the poles of the magnets 108, 110, 112, 114 (illustrated as “N” and “S” in keeping with convention) are shown in a “vertical” alignment parallel to the rotational axis 120 as depicted. However, it is appreciated that some other angle (i.e., other than parallel to the rotational axis 120) may be employed for this purpose. Additionally, the poles of each magnet 108, 110, 112, 114 are oriented to alternate relative to their neighbors. Thus, in the illustrated embodiment, the North pole of a first magnet 108 faces the magnetic sensor 102 whereas the South poles of the first magnet's neighbors 110, 114 face the magnetic sensor.

Stated generally, the magnetic sensor 102 is maintained in a fixed position relative to a plane in which the magnets rotate. For example, in an embodiment best shown in FIGS. 2 and 3, the magnetic sensor 102 is arranged in a first plane 130 and the magnet assembly 104 is arranged in a second plane 140, which planes are both perpendicular to the rotational axis, i.e., parallel to each other. As used herein, arrangement of an element in a plane denotes co-planarity of the element and the plane, e.g., the condition in which a substantially planar surface of the element lies in the plane. Thus, as shown in FIGS. 2 and 3, a lower surface of the magnetic sensor 102 lies in the first plane 130, whereas an upper surface of the magnet assembly 104 lies in the second plane 140. However, it is appreciated that the planes 130, 140 need not be parallel to each other in all instances. The first and second planes 130, 140, and consequently the magnetic sensor 102 and magnet assembly 104, are also in proximity to each other. As used in this case, proximity denotes the condition of the magnetic sensor 102 and magnet assembly 104 being sufficiently close to and aligned with each other such that the magnetic sensor 102 is able to consistently and accurately detect magnetic fields provided by the magnet assembly 104. As will be appreciated by those of skill in the art, the distance between the magnetic sensor 102 and magnet assembly is a function of the sensitivity of the magnetic sensor 102 and the magnets in the magnet assembly 104. As a non-limiting example, in a current implementation, the magnetic sensor 102 may be placed anywhere from 0 to 3 millimeters from the plane 140 of the magnets and, in a presently preferred embodiment, is placed approximately 0.5 to 1.8 millimeters away.

FIG. 3 best illustrates alignment of the magnetic sensor 102 and the magnets 108, 110, 112, 114 relative to the rotational axis 120. As shown, the magnetic sensor is positioned at a first radius (R1) relative to the rotational axis 120 and each of the magnets 108, 110, 112, 114 is positioned at a second radius (R2) relative to the rotational axis 120, where the first radius is not equal to the second radius. In particular, a detection axis 103 (i.e., an axis of symmetry of the magnetic detection element within the magnetic sensor) of the magnetic sensor 102 is positioned at the first radius whereas an axis 103 of each of the magnets 108, 110, 112, 114 (e.g., an axis of symmetry of each magnet) is positioned at the second radius. The difference between the first and second radius may be selected as a matter of design choice as dictated by the sensitivity of the magnetic sensor 102 and the relative strength of the magnets 108, 110, 112, 114. Once again, in all instances, the difference between the first and second radiuses should be selected, taking into account the relative strength of the magnets and the sensitivity of the magnetic sensor, to ensure that the magnetic sensor 102 is able to consistently and reliable detect the magnetic fields of the magnets 108, 110, 112, 114. By way of an additional, non-limiting example, using an iC-MH sensor and four, cylindrical permanent magnets approximately 3.175 millimeters in diameter and 6.35 millimeters long, the magnets may each be positioned approximately 3.2 millimeters away from the rotational axis whereas the magnetic sensor may be positioned approximately 1.5 millimeters away from the rotational axis.

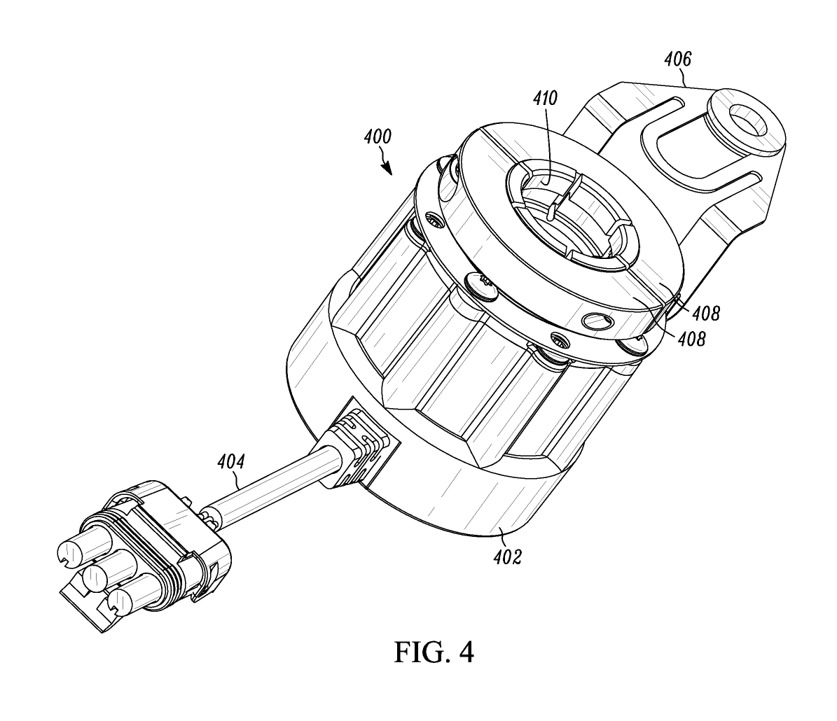

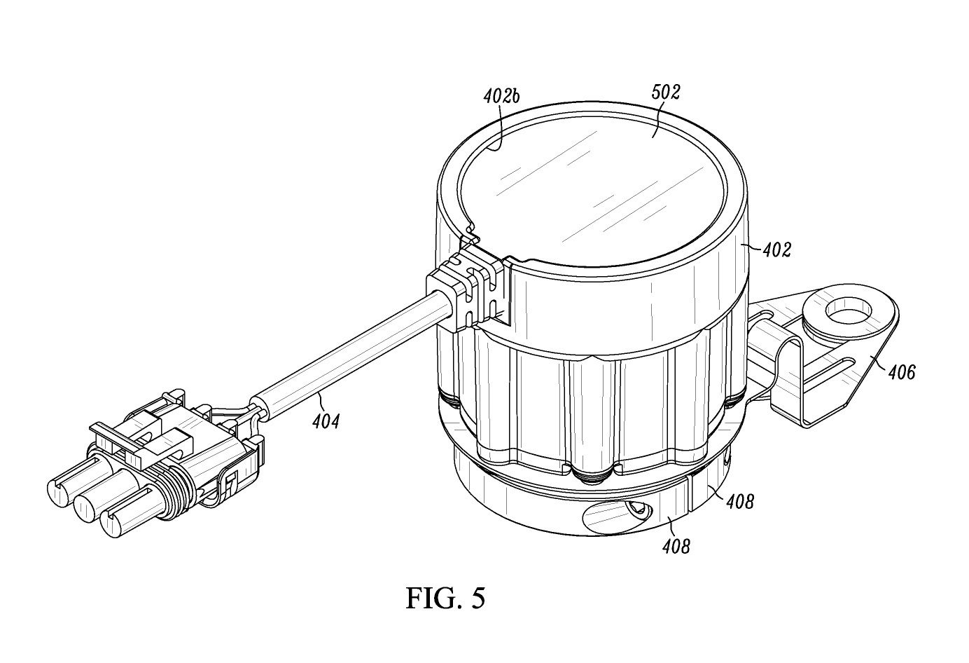

Referring now to FIGS. 4-7, a rotational sensor 400 is illustrated. In the illustrated embodiment, the rotational sensor 400 comprises an housing 402 substantially enclosing a rotatable shaft 410. A cable assembly 404 is coupled to and extends away from the housing 402. As shown, the cable assembly 404 comprises a suitable connector permitting reliable electrical connections for the transfer of data from the magnetic sensor 102. An anti-rotation tether 406 is also coupled to the housing 402 and is configured to permit attachment of the tether 406 to any suitable structure, preferably via a tether bushing 612, to substantially prevent rotation of the housing 402 when the rotational sensor 400 is attached to a rotating member. A two-piece collar clamp 408 is provided to secure rotatable shaft 410 and, consequently, the housing 402 to the rotating member as described in greater detail below. As best shown in FIG. 5, an encapsulant 502 may be provided in an open end 402b of the housing 402 to shield the magnetic sensor 102 and related components from the environment in which the rotational sensor 400 is deployed. The encapsulant may comprise a suitable material that is initially flowable and that subsequently sets/cures into a relatively rigid form, and that is compatible with the anticipated environment. For example, for use in an agricultural environment, in which exposure to grease, oil, diesel fuel, dirt, moisture, temperature extremes, etc. can be anticipated, a suitable two-component epoxy potting compound as manufactured by EFI Polymers may be used.

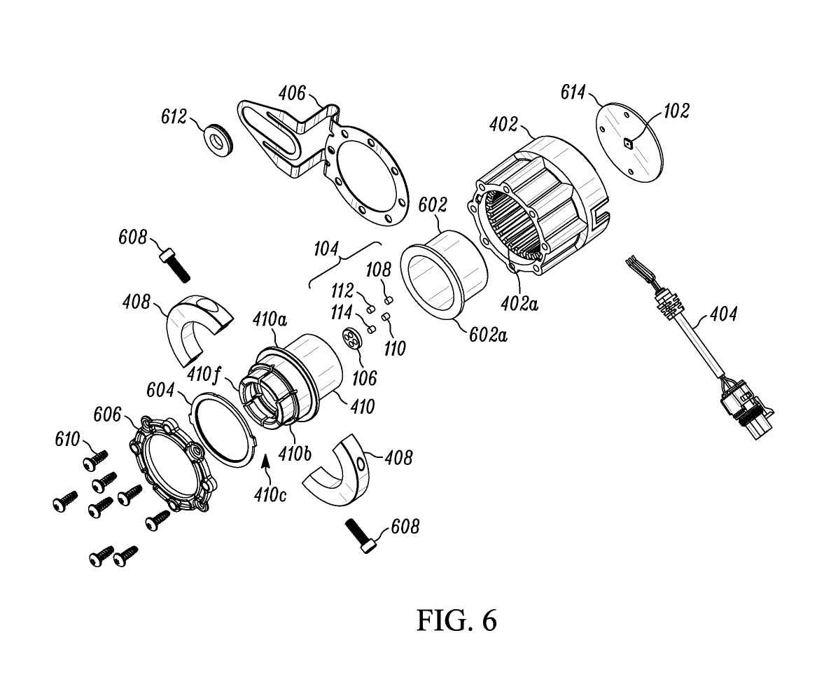

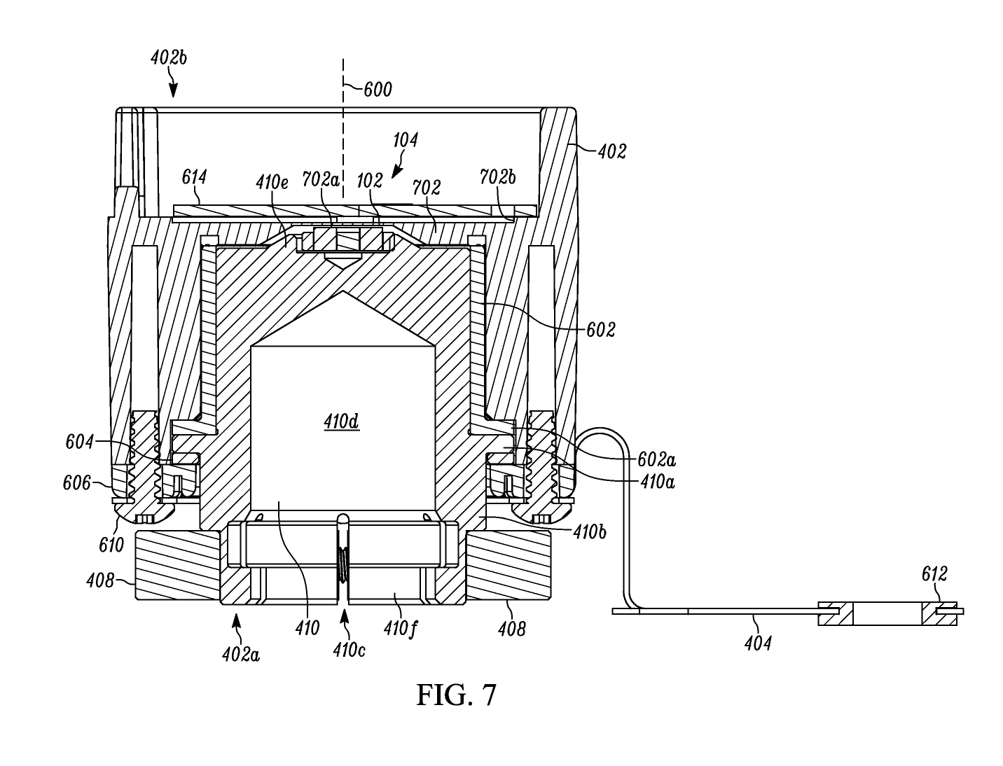

Construction of the rotational sensor 400, as well as its further constituent components, is illustrated in further detail with reference to FIGS. 6 and 7. In particular, the housing 402 is generally cylindrical along a longitudinal axis 600. As best illustrated in FIG. 7, the longitudinal axis 600 is substantially aligned with the rotational axis 120 of the magnet assembly 104. In an embodiment, the housing 402 may be fabricated from a suitably strong and durable synthetic polymer and non-magnetic material such as polybutylene terephthalate (PBT) thermoplastic resin. A central bore in the housing has a first open end 402a and a second, opposite open end 402b. As further shown in FIG. 7, the housing 402 may comprise a transverse internal wall 702 within the central bore and that defines two separate cavities therein, which cavities are respectively accessible via the first open end 402a and the second open end 402b.

The rotatable shaft 410 is configured to be received in the first open end 402a along with a sleeve bearing 602 interposed between the shaft 410 and the housing 402. In an embodiment, the rotatable shaft 410 is fabricated from 316 Stainless Steel with an electroless nickel plating and the sleeve bearing 602 is fabricated from a suitable synthetic polymer material. Generally, the rotatable shaft 410 may be fabricated from either a magnetic or non-magnetic material though, in the noted embodiment, a non-magnetic stainless steel is used to eliminate any potential magnetic field distortions. In the illustrated embodiment, the sleeve bearing 602 has a bearing flange 602a at its lower end configured to engage with a shaft flange 410a on the rotatable shaft 410. As best shown in FIG. 7, the shaft flange 410a maintains the bearing sleeve 602 in position between the rotatable shaft 410 and the housing 402. As further shown in FIG. 7, the bearing sleeve 602 is open at both of its ends such that the rotatable shaft 410 is received at one end of the bearing sleeve and extends out of (or is at least exposed at) the other end of the bearing sleeve.

Referring to FIG. 7, the rotatable shaft 410 has a shaft central bore 410d, which in the illustrated embodiment is a blind bore having an end surface 410e. A diameter of the shaft central bore 410d may be selected as a matter of design choice, typically dependent upon the particular application for the rotational sensor 400. The magnet assembly 104 is mounted on the end surface face 410e facing the internal wall 702. The rotatable shaft 410 is configured, and the magnet assembly 104 mounted, such that the rotational axis 120 of the magnet assembly 104 is aligned with the longitudinal axis of the housing. In an embodiment, the magnet assembly 104, when mounted on the rotatable shaft 410 in substantial proximity to (e.g., within 0.25 to 0.76 millimeters) the internal wall 702. In order to maximize the strength of the magnetic fields reaching the magnetic sensor 102 from the magnet assembly 104, the internal wall 702 may comprise a reduced-thickness portion 702a aligned with the magnet assembly.

The rotatable shaft 410 is retained in the housing by a washer 604 and cover 606 that, in turn, is secured to the housing by screws 610 or other suitable fasteners. Similar to bearing flange 602a, the washer 604 serves as a thrust washer for the sleeve bearing 602 and, in an embodiment, is manufactured from the same polymer material as the sleeve bearing 602. The rotatable shaft 410 includes a number of longitudinal splits 410c extending from the open end of the shaft central bore 410d into the outer wall of the rotatable shaft 410, effectively forming a number of cantilevered arms 410f. The rotatable shaft 410 further comprises a shoulder 410b that acts as a stop for the collar clamp 408. When the rotatable shaft 410 is mounted on the rotating member (not shown) to be measured, screws or other fasteners 608 may be used to tighten the collar clamp 408 around the rotatable shaft 410 in the region of the cantilevered arms 410f. The clamping force of the collar clamp 408 causes the cantilevered arms 410f to flex inwardly to the extent permitted by the rotating member engaged therein. In this manner, the rotatable shaft 410 is securely mounted on the rotating member such that all movement of the rotating member is imparted on rotatable shaft 410 and, consequently, the magnet assembly 104.

As further shown, the magnetic sensor 102 is mounted on a surface of a circuit board 614. As noted above, the circuit board 614 may comprise any necessary or desired circuitry to operate and obtain useful signals from the magnetic sensor 102. Although not shown in FIG. 7, the circuit board 614 may terminate wires from the cable assembly 404 used to convey the signals provided by the magnetic sensor 102 and to provide power or control signals to the magnetic sensor 102. Note that the encapsulant 502 is likewise not shown in FIG. 7. In an embodiment, the internal wall 702 may further comprise a shoulder 702b facing the second open end 402b and forming a recess of a diameter smaller than a diameter of the circuit board 614 and having a depth substantially equal to the height of the magnetic sensor 102 when mounted on the circuit board 614. The magnetic sensor 102 is mounted to the circuit board 614 such that, when the circuit board is placed above the recess formed by the shoulder 702b, the magnetic sensor is maintained in proximity to or, preferably, in direct contact with the internal wall 702 and at the first radius (R1) away from the rotational/longitudinal axis 120, 600. Although not shown in the Figures, suitable fasteners may be used to secure the circuit board 614 to the housing 402 prior to being covered by the encapsulant 502.

While particular preferred embodiments have been shown and described, those skilled in the art will appreciate that changes and modifications may be made without departing from the instant teachings. For example, in an alternative arrangement, a second rotary shaft off-axis relative to the rotatable shaft 410 and connected thereto by a gear train or other linkage may be provided. To the extent that this second rotary shaft would therefore rotate in unison (subject to any gear or speed ratio provided by the gear train/linkage) with the rotatable shaft 410, the magnet assembly 104 could be mounted on the second rotary shaft and, likewise, the magnetic sensor 102 could be disposed relative to the second rotary shaft.

It is therefore contemplated that any and all modifications, variations or equivalents of the above-described teachings fall within the scope of the basic underlying principles disclosed above and claimed herein.

What is claimed is:

1. A rotational sensor comprising:
a multi-pole magnet assembly comprising a plurality of magnets, each of the plurality of magnets configured to rotate about a rotational axis and in a first plane perpendicular to the rotational axis; and
a magnetic sensor arranged in a second plane perpendicular to the rotational axis and in proximity to the multi-pole magnet assembly,
wherein each magnet of the plurality of magnets has poles aligned parallel to the rotational axis and perpendicular to the first plane of the magnetic sensor.

2. The rotational sensor of claim 1, wherein the magnetic sensor is arranged at a first radius away from the rotational axis.

3. The rotational sensor of claim 2, wherein the plurality of magnets are arranged at a second radius, not equal to the first radius, away from the rotational axis.

4. The rotational sensor of claim 1, wherein the plurality of magnets are arranged circumferentially equidistant from each other.

5. A rotational sensor comprising:
a multi-pole magnet assembly comprising a plurality of magnets, each of the plurality of magnets configured to rotate about a rotational axis and in a first plane perpendicular to the rotational axis; and
a magnetic sensor arranged in a second plane perpendicular to the rotational axis and in proximity to the multi-pole magnet assembly,
wherein the magnetic sensor is arranged at a first radius away from the rotational axis and the plurality of magnets are arranged at a second radius, not equal to the first radius, away from the rotational axis.

6. The rotational sensor of claim 5, wherein the plurality of magnets are arranged circumferentially equidistant from each other.

7. A rotational sensor for detecting rotation of a rotating member, the rotational sensor comprising:
an housing having a longitudinal axis and comprising a housing central bore centered on and extending along the longitudinal axis;
a rotatable shaft configured to be received in the housing central bore, the shaft comprising a shaft central bore configured to receive the rotating member and further comprising an end surface substantially perpendicular to the longitudinal axis;
at least one magnet supported by the end surface of the rotatable shaft, the at least one magnet positioned to rotate about the longitudinal axis and arranged to have poles of the at least one magnet aligned substantially parallel to the longitudinal axis; and
a magnetic sensor arranged in a plane parallel to the end surface of the shaft and in proximity to the at least one magnet along the longitudinal axis.

8. The rotational sensor of claim 7, wherein the housing and the rotatable shaft are fabricated from at least one non-magnetic material.

9. The rotational sensor of claim 7, wherein the housing and the rotatable shaft are fabricated from a synthetic polymer.

10. The rotation sensor of claim 7, wherein the shaft central bore is a blind bore and the end surface is provided by an end wall of the shaft central bore.

11. The rotation sensor of claim 7, wherein the magnetic sensor is aligned at a first radius away from the longitudinal axis.

12. The rotation sensor of claim 7, wherein the at least one magnet is positioned in proximity to the longitudinal axis.

13. The rotation sensor of claim 7, wherein the at least one magnet is positioned in proximity to a circumferential edge of the rotatable shaft .

14. The rotation sensor of claim 7, wherein the at least one magnet comprises four magnets, each of the four magnets having its respective poles aligned parallel to the longitudinal axis, the four magnets placed at a second radius away from the longitudinal axis and circumferentially equidistant from each other.

15. The rotation sensor of claim 7, further comprising:
a sleeve bearing between the housing and the rotatable shaft.

16. The rotation sensor of claim 15, wherein the sleeve bearing is fabricated from a synthetic polymer.

17. The rotation sensor of claim 7, further comprising:
a circuit board configured to support the magnetic sensor,
wherein the housing comprises a first open end configured to receive the rotatable shaft and a second open end opposite the first open end configured to receive the circuit board.

18. The rotation sensor of claim 17, further comprising:
an encapsulant placed in the second open end and covering the circuit board.
